(19) United States
(12) Patent Application Publication
(10) Pub. No.: US 2015/0259196 A1
(43) Pub. Date: Sep. 17, 2015

(54) MEMS DEVICE AND METHOD OF MANUFACTURING THE SAME

(71) Applicant: KABUSHIKI KAISHA TOSHIBA, Tokyo (JP)

(72) Inventor: Naofumi NAKAMURA, Tokyo (JP)

(73) Assignee: KABUSHIKI KAISHA TOSHIBA, Tokyo (JP)

(21) Appl. No.: 14/476,409

(22) Filed: Sep. 3, 2014

(30) Foreign Application Priority Data
Mar. 13, 2014 (JP) 2014-049677

(51) Int. Cl. B81B 7/00; B81C 1/00

(52) U.S. Cl. CPC B81B 7/0038; B81C 1/00476; B81C 1/00285

(57) ABSTRACT

According to one embodiment, a MEMS device is disclosed. The device includes a substrate, a MEMS element provided on the substrate, a first film having a plurality of through holes. The first film and the substrate form a cavity containing the MEMS element. The device further includes a second film provided on the first film, a third film provided on the substrate, and including a first region and a second region outside the first region, the first region and the second region being different from each other in height from the substrate. The height from the substrate of the first region of the third film is lower than the height from the substrate of the second region of the third film.

### CROSS-REFERENCE TO RELATED APPLICATIONS

This application is based upon and claims the benefit of priority from Japanese Patent Application No. 2014-049677, filed Mar. 13, 2014, the entire contents of which are incorporated herein by reference.

### FIELD

Embodiments described herein relate generally to a MEMS device including a MEMS (Micro Electro Mechanical Systems) element and a manufacturing method of the same.

### BACKGROUND

As one of methods for manufacturing a MEMS device, there is known a method which includes forming encapsulated MEMS elements on a surface of a wafer, thinning the wafer by polishing its back side in a state that the encapsulated MEMS devices are fixed by tape, and dividing the MEMS devices into individual pieces by dicing the thinned wafer.

The MEMS element comprises a fixed electrode (lower electrode) formed on the substrate, and a movable electrode (upper electrode) formed above the fixed electrode. A diaphragm is further formed on the substrate. The substrate and the diaphragm form a cavity containing the fixed electrode and the movable electrode. The MEMS element is encapsulated by the substrate and the diaphragm. The diaphragm includes a cap film having through holes, and a cap film formed on the above cap film and closing the through holes.

### BRIEF DESCRIPTION OF THE DRAWINGS

FIG. 1 is a sectional view for illustrating a manufacturing method of a MEMS device according to a first embodiment;

FIG. 2 is a sectional view for illustrating the manufacturing method of the MEMS device according to the first embodiment following FIG. 1;

FIG. 3 is a sectional view for illustrating the manufacturing method of the MEMS device according to the first embodiment following FIG. 2;

FIG. 4 is a sectional view for illustrating the manufacturing method of the MEMS device according to the first embodiment following FIG. 3;

FIG. 5 is a sectional view for illustrating the manufacturing method of the MEMS device according to the first embodiment following FIG. 4;

FIG. 6 is a sectional view for illustrating the manufacturing method of the MEMS device according to the first embodiment following FIG. 5;

FIG. 7 is a sectional view for illustrating the manufacturing method of the MEMS device according to the first embodiment following FIG. 6;

FIG. 8 is a sectional view for illustrating the manufacturing method of the MEMS device according to the first embodiment following FIG. 7;

FIG. 9A is a sectional view for illustrating the manufacturing method of the MEMS device according to the first embodiment following FIG. 8;

FIG. 9B is a plan view showing a plane pattern of a third cap film in FIG. 9A;

FIG. 10A is a sectional view for illustrating the manufacturing method of the MEMS device according to the first embodiment following FIG. 9A;

FIG. 10B is a plan view showing a plane pattern of the third cap film in FIG. 10A;

FIG. 11 is a sectional view for illustrating the manufacturing method of the MEMS device according to the first embodiment following FIG. 10A;

FIG. 12 is a sectional view for illustrating a problem in a comparative example;

FIG. 13 is a sectional view for illustrating a MEMS device according to a second embodiment;

FIG. 14 is a sectional view for illustrating a forming method of an anchor portion of the MEMS device according to the second embodiment;

FIG. 15 is a sectional view for illustrating the forming method of the anchor portion of the MEMS device according to the second embodiment following FIG. 14;

FIG. 16 is a sectional view for illustrating a MEMS device according to a third embodiment;

FIG. 17 is a plan view showing a plane pattern of a third cap film of the MEMS device according to the third embodiment;

FIG. 18 is a sectional view for illustrating a forming method of the third cap film of the MEMS device according to the third embodiment;

FIG. 19 is a sectional view for illustrating a forming method of the third cap film of the MEMS device according to the third embodiment following FIG. 18;

FIG. 20 is a sectional view for illustrating a forming method of the third cap film of the MEMS device according to the third embodiment following FIG. 19;

FIG. 21 is a sectional view for illustrating a variation of the MEMS device of the third embodiment;

FIG. 22 is a plan view showing a third cap film of the variation of the MEMS device of the third embodiment;

FIG. 23 is a plan view showing a third cap film of another variation of the MEMS device of the third embodiment; and

FIG. 24 is a sectional view for illustrating a variation of the MEMS device of the first embodiment.

### DETAILED DESCRIPTION

Embodiment will be described below with reference to the drawings. In the drawings, portions identical or corresponding to each other are denoted by the same reference numbers, and the same description may be repeated as necessary.

In general, according to one embodiment, a MEMS device is disclosed. The device includes a substrate, a MEMS element provided on the substrate, a first film having a plurality of through holes, the first film and the substrate forming a cavity containing the MEMS element. The device further includes a second film provided on the first film, a third film provided on the substrate, and including a first region and a second region outside the first region, the first region and the second region being different from each other in height from the substrate. The height from the substrate of the first region of the third film is lower than the height from the substrate of the second region of the third film.

According to one embodiment, a method for manufacturing a MEMS device is disclosed. The method includes forming a MEMS element on a substrate, forming a sacrifice layer covering the MEMS element on the substrate, forming a first film having a plurality of through holes on the sacrifice layer, and removing the sacrifice layer via the plurality of through holes to form a cavity containing the MEMS element. The cavity includes the substrate and the first film. The method further includes forming a second film on the first film to close the plurality of through holes, forming a third film including a first region and a second region outside the first region on the second film. The first region and the second region are different in height from the substrate, and the height from the substrate of the first region of the third film is lower than that of the second region of the third film.

### First Embodiment

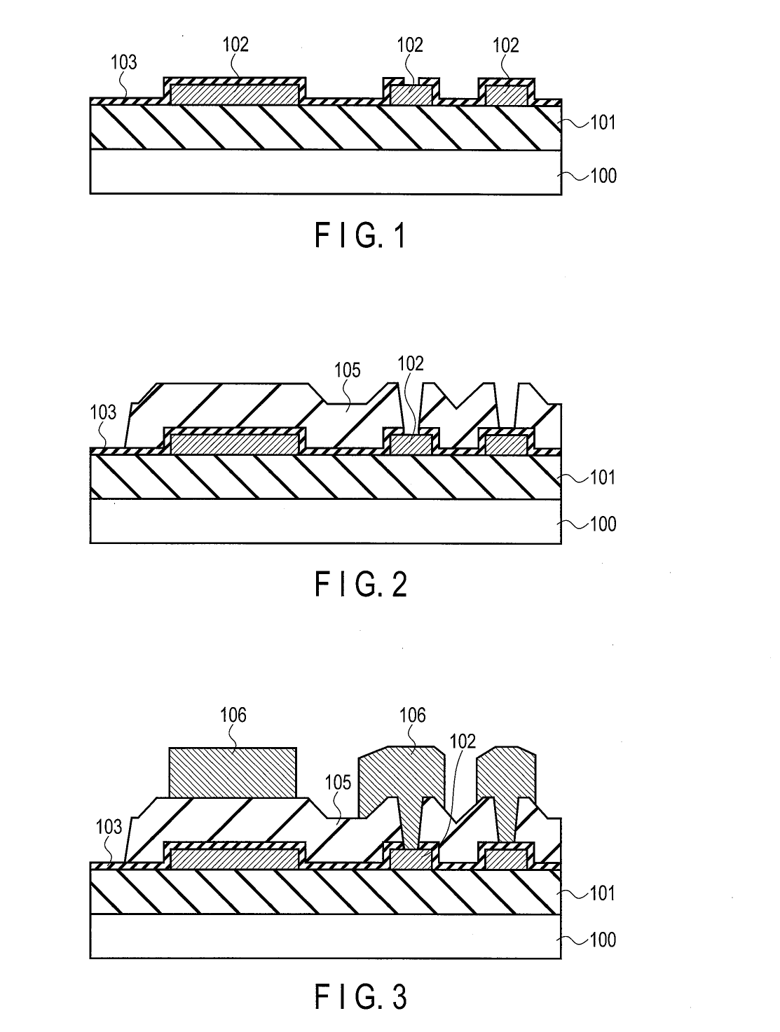

FIGS. 1 to 11 are sectional views for illustrating a method of manufacturing a MEMS device. The present embodiment provide an explanation in a case where each MEMS elements of MEMS devices is collectively encapsulated on a wafer by a thin-film in a front-end process (inline WLP (Wafer Level Package)), but in the following explanation, for the sake of brevity, the explanation is for one MEMS device. The MEMS device of the present embodiment is used for an RF capacitor, for example.

[FIG. 1]

An insulating film 101 is formed on a semiconductor substrate 100. The semiconductor substrate 100 is, for example, a silicon substrate.

Other semiconductor substrate such as an SOI substrate may be used instead of the silicon substrate. The insulating film 101 is, for example, a silicon oxide film. Hereafter, the semiconductor substrate 100 and the insulating film 101 may be collectively referred to as a substrate.

Next, a conductive film to be processed into a first interconnect (fixed electrode) 102 is formed on the insulating film. The first interconnect 102 is formed by processing the above conductive film using photolithography method and etching method. The etching is, for example, RIE (Reactive Ion Etching) method. Wet etching method may be used instead of RIE method. The conductive film is, for example, an aluminum film. This aluminum film is formed by using, for example, sputtering method. A thickness of the first interconnect is, for example, a few hundred nm to a few μm.

Next, a passivation film 103 is formed on a region including the insulating film 101 and the first interconnect 102, and a through hole reaching the first interconnect 102 is formed in the passivation film 103 by using photolithography method and RIE method. The passivation film 103 is formed by, for example, CVD (Chemical Vapor Deposition) method. The passivation film 103 is, for example, an insulating film such as silicon oxide film or silicon nitride film.

[FIG. 2]

A first sacrifice layer 105 having a predetermined shape is formed on the first interconnect 102 and the passivation film 103. The first sacrifice layer 105 has a through hole communicating with the through hole of the passivation film 103. The first sacrifice layer 105 is, for example, an insulating film using organic substance such as polyimide as a material. A thickness of the first sacrifice layer 105 is, for example, a few hundred nm to a few μm.

In order to form the first sacrifice layer 105, for example, there are following three methods.

In the first method, an insulating film (coating film) with a few hundred nm to a few μm thickness, which is to be processed into the first sacrifice layer 105, is formed on the entire surface by coating method, thereafter, unnecessary portion of the above coating film is removed by lithography and development, thereby the first sacrifice layer 105 having the predetermined shape is formed.

In the second method, after forming the coating film, a resist pattern is formed on the coating film by using lithography, then the coating film is etched by RIE method using the resist pattern as a mask, thereby the first sacrifice layer 105 having the predetermined is formed.

In the third method, the coating film is formed, thereafter, a hard mask is formed on the coating film, then the coating film is etched by RIE method or wet process using the hard mask as a mask, thereby the first sacrifice layer 105 having the predetermined is formed. The step of forming the hard mask includes a step of forming an insulating film such as a silicon oxide film or silicon nitride film on the coating film, a step of forming a resist pattern on the insulating film, and a step of etching the insulating by RIE method using the resist pattern as a mask.

[FIG. 3]

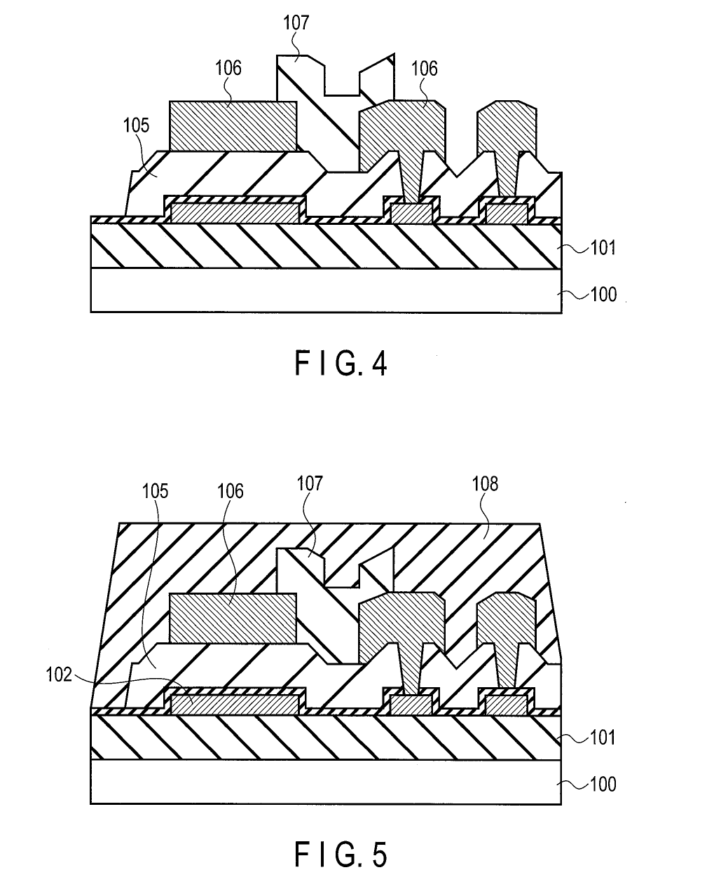

A conductive such as an aluminum film is formed on the entire surface to fill the through holes of the passivation film 103 and the first sacrifice layer 105, thereafter, the conductive film is processed to form second interconnects (movable electrodes). The process for the conductive film is performed by using, for example, lithography method and RIE method. In stead of RIE method, wet etching may be used. A thickness of the second interconnect 106 is, for example, a few hundred nm to a few μm. The middle one of the second interconnect 106 shown in FIG. 3, is connected to the first interconnect 102 via the through holes of the passivation film 103 and the first sacrifice layer 105.

[FIG. 4]

A insulating film such as silicon nitride film with a few hundred nm to a few μm thickness is deposited by CVD method, thereafter, the insulating film is processed by using photolithography method and etching method to form an insulating connection portion (spring) 107 connecting the second interconnects 106. Thus the MEMS elements are completed. Here, the insulating connection portion is exemplified, but, a connection portion formed of metal, i.e., conductive connection portion may be used.

[FIG. 5]

Following that, a WLP (Wafer Level Package) process proceeds.

A second sacrifice layer 108 having a predetermined shape to cover a region including the fixed electrode 102, the movable electrode 106 and the connection portion 107 of the MEMS element is formed. An upper surface of the second sacrifice layer 108 is, for example, flat. The second sacrifice layer 108 is obtained by forming a film (coating film) employing organic substance such as polyimide as a material with a few hundred nm to a few μm thickness by coating method, and then by patterning the coating film, for example.

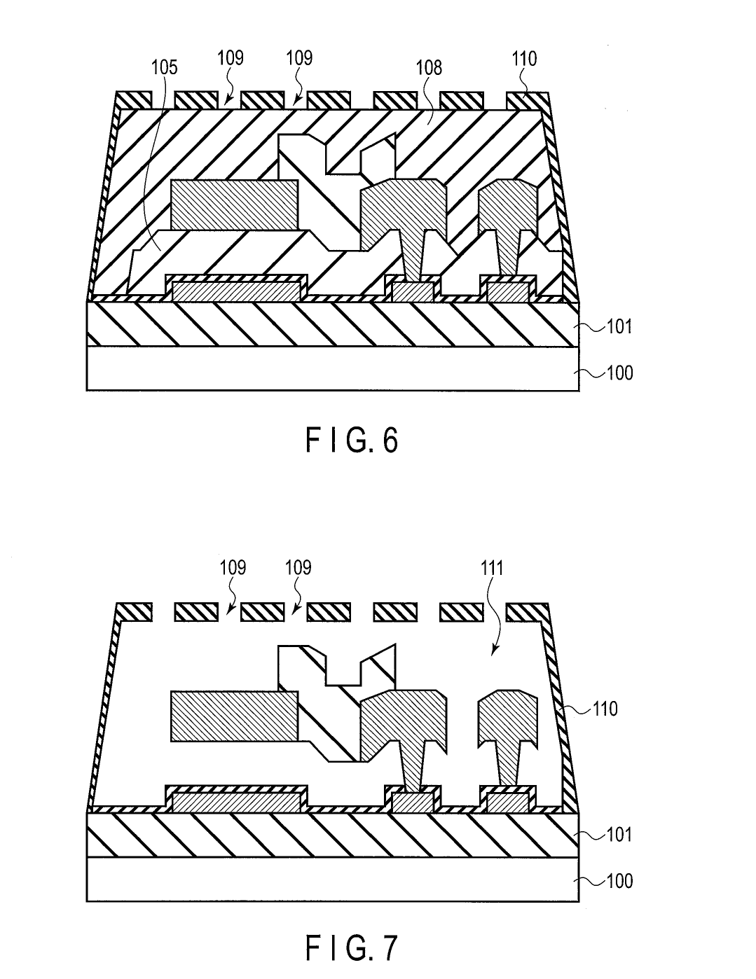

Relating to the patterning method of the coating film, a method that includes removing unnecessary portions of the second sacrifice layer 108 by exposure and development after the coating of the second sacrifice layer 108, or a method that includes forming a resist pattern on the second sacrifice layer 108 by using lithography method, and removing unnecessary portions of the second sacrifice layer 108 by etching the second sacrifice layer 108 by RIE method using the resist pattern as a mask, or a method that includes forming a hard mask on the second sacrifice layer 108, and removing unnecessary portions of the second sacrifice layer 108 by etching the second sacrifice layer 108 by RIE method or wet process using the hard mask as a mask, may be provided.

[FIG. 6]

A first cap film 110 having through holes 109 is formed on the second sacrifice layer 108. In the present embodiment, the through holes 109 are formed on an upper surface (ceiling) of the first cap film 110. The through holes 109 are used to supply gas for removing the first and sacrifice layers 105 and 108 into the first cap film 110. The first cap film 110 is an inorganic film (for example, silicon oxide film) having a few hundred nm to a few μm thickness. The first cap film 110 is formed by, for example, CVD process.

The through holes 109 are obtained, for example, by forming a resist pattern (not shown) having through holes on the inorganic film, and by processing the inorganic film by RIE method or wet etching method using the resist pattern as a mask.

[FIG. 7]

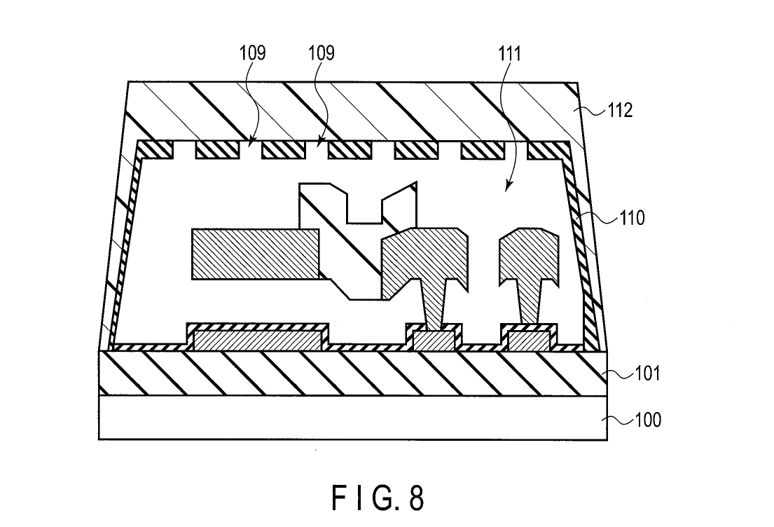

The resist pattern having the through holes, the first sacrifice layer 105, and the second sacrifice layer 108 are removed by ashing using oxygen (O₂) gas or the like. Thereby, the MEMS element is released, and the cavity 110 that is an operation space for the MEMS element is formed by the semiconductor substrate 100 and the first cap film 110.

[FIG. 8]

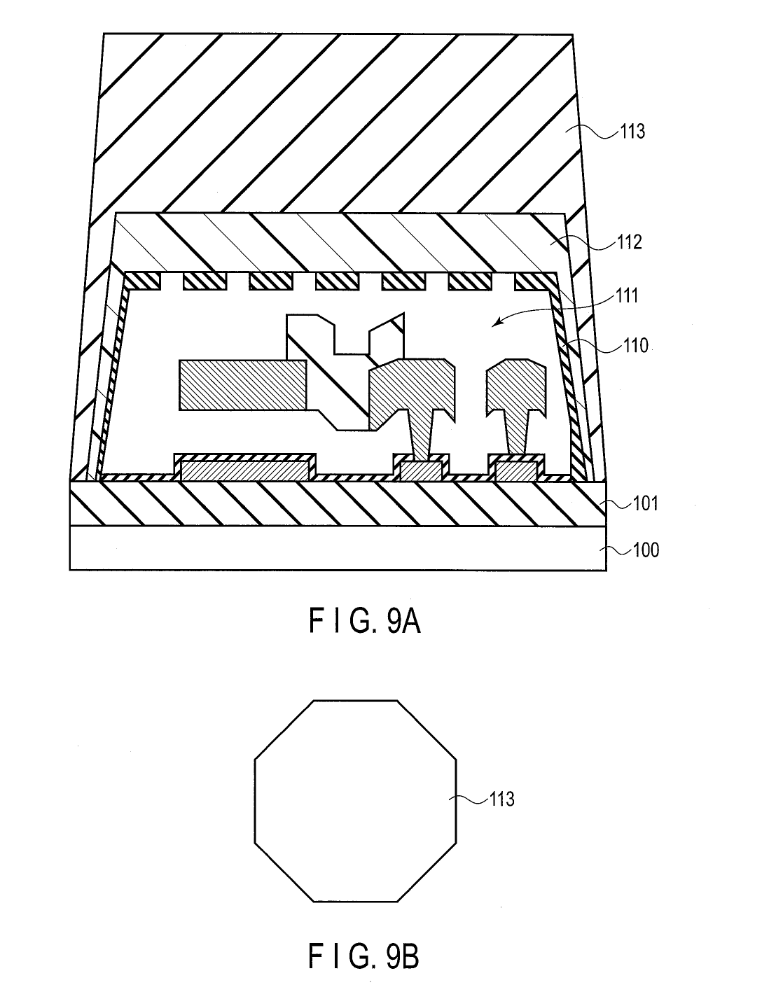

A second cap film 112 is formed on the first cap film 110 by coating method. In the present embodiment, the second cap film 112 is an organic film (insulating film) which uses organic substance such as polyimide series resin as a material. In this case, the second cap film 112 can be formed to fill the through holes of the first cap film 110, and the second cap film 112 has a higher gas permeability than the first cap film 110. The second cap film 112 is not needed to fill the through holes as long as the second cap film 112 closes the through holes.

[FIG. 9A and FIG. 9B]

A third cap film 113 is formed on the second cap film 112. FIG. 9B shows a plane pattern of the third cap film 113, and in the present embodiment, the third cap film 113 has an octagonal plane pattern, but the plane pattern is not limited to the octagonal plane pattern. The third cap film works as a moisture-resistant film. For this purpose, the third cap film 113 preferably has a lower gas permeability than the second cap film 112. Such a relationship in gas permeability can be established by, for example, when the third cap film 113 is a deposition film by CVD method, and the second cap film 112 is a coating film by spin coating method.

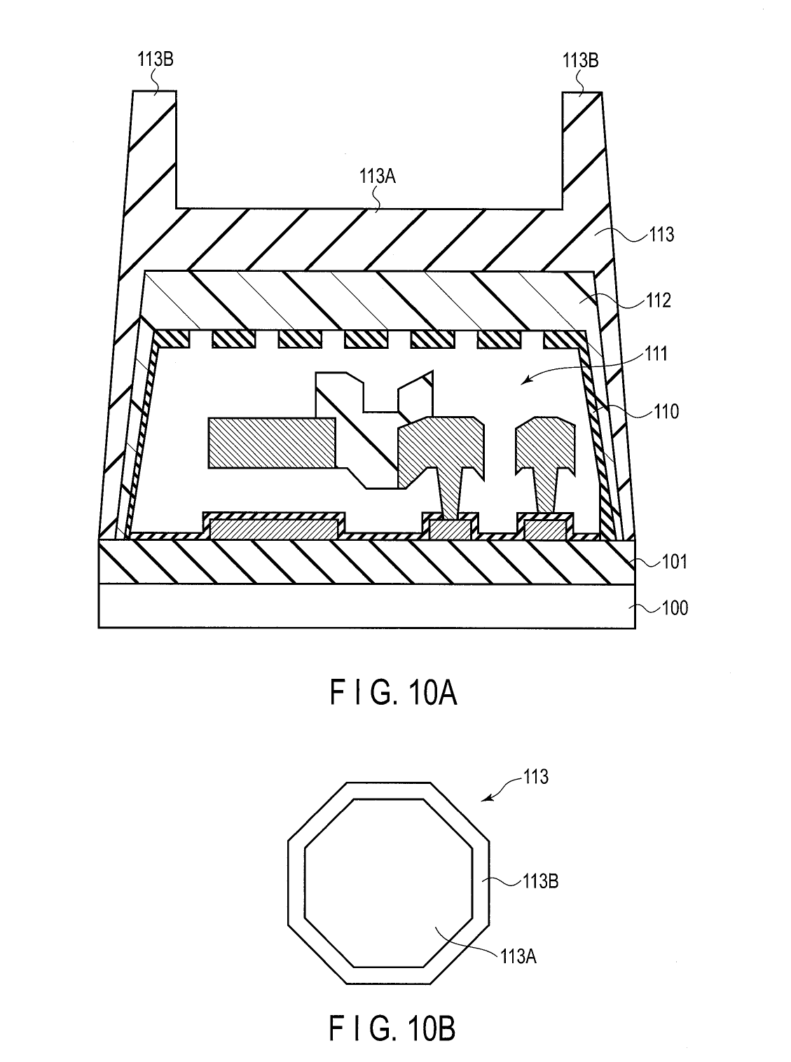

The process for forming the third cap film 113 includes forming an insulating film such as silicon nitride film with a few hundred nm to a few μm thickness by CVD method, forming a resist pattern having the plane pattern of octagon on the insulating film by using photolithography method, processing the insulating film by RIE method or wet etching method using the resist pattern as a mask.

[FIG. 10A and FIG. 10B]

The third cap film 113 is processed by using lithography method and etching method to modify the third cap film 113 to have a film 113A provided on a first region and a film 113B provided on a second which are different each other in height from the substrate. FIG. 10B shows a plan view of the third cap film 113 having the films 113A, 113B.

The film 113A is lower than the film 113B in height from the substrate, the film 113B is provided outside the film 113A, and is arranged to surround the film 113A.

The upper portion side of the thin-film dome (cap films 110, 112, 113) of WLP of the present embodiment has a shape that the height of central portion (film 113A) is lower than the height of peripheral portion (film 113B).

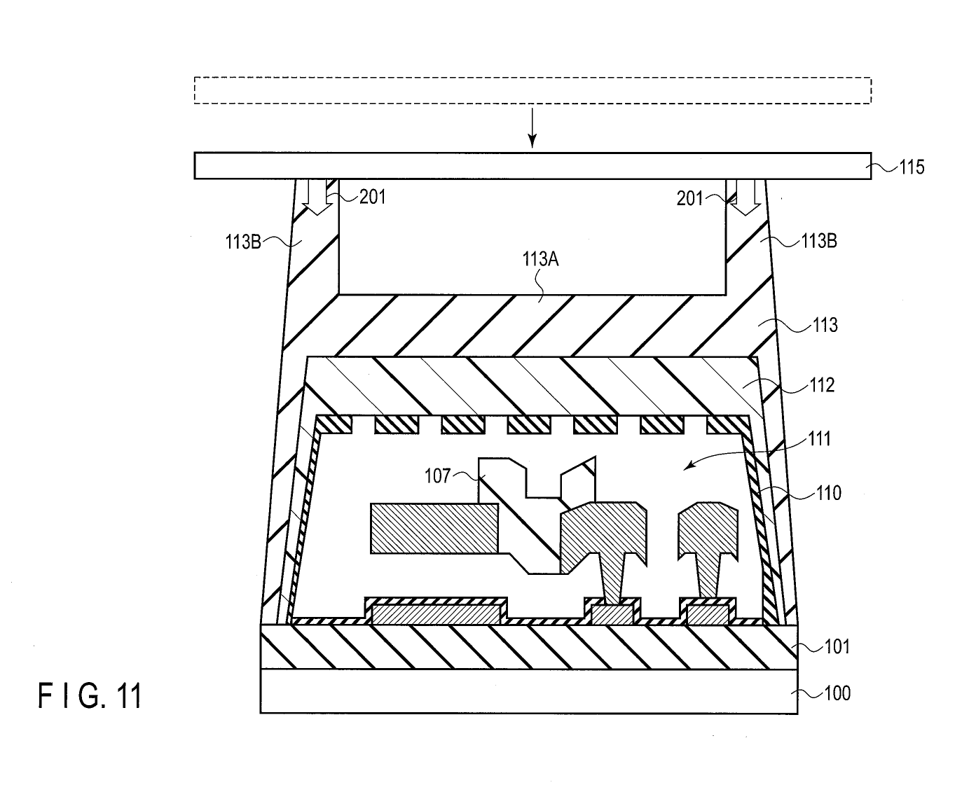

In the step of FIG. 9, for example, when a silicon nitride film with 10 μm thickness is formed as the third cap film 113, the height of the film 113A is lower than the height of the film 113B by, for example 7 μm. In this case, a remaining thickness of the film is 3 μm. The structure having such a height difference (recess structure) is formed by, for example, the following process. That is, the recess structure is obtained by forming a resist pattern (not shown) having a plane pattern of octagon on the silicon nitride film, and etching the silicon nitride film by using RIE method with the resist pattern as a mask.

[FIG. 11]

A dicing tape 115 is disposed above the third cap film 113, and an adhesive face of the dicing tape 115 is applied to the upper surface of the third cap film 113 to fix the MEMS device on the dicing tape 115.

When the dicing tape 115 is applied to the third cap film 113, the film 113B of the third cap film 113 receives a force 201 from the dicing tape 115. However, the film 113A of the third cap film 113 does not receive the force from the dicing tape 115. As a result, the film 113A arranged on the MEMS element is suppressed from being deformed, and the thin-film dome (cap films 110, 112, 113) is suppressed from being deformed. The magnitude of the force 201 is, for example, 5 to 10 times as strong as the atmospheric pressure.

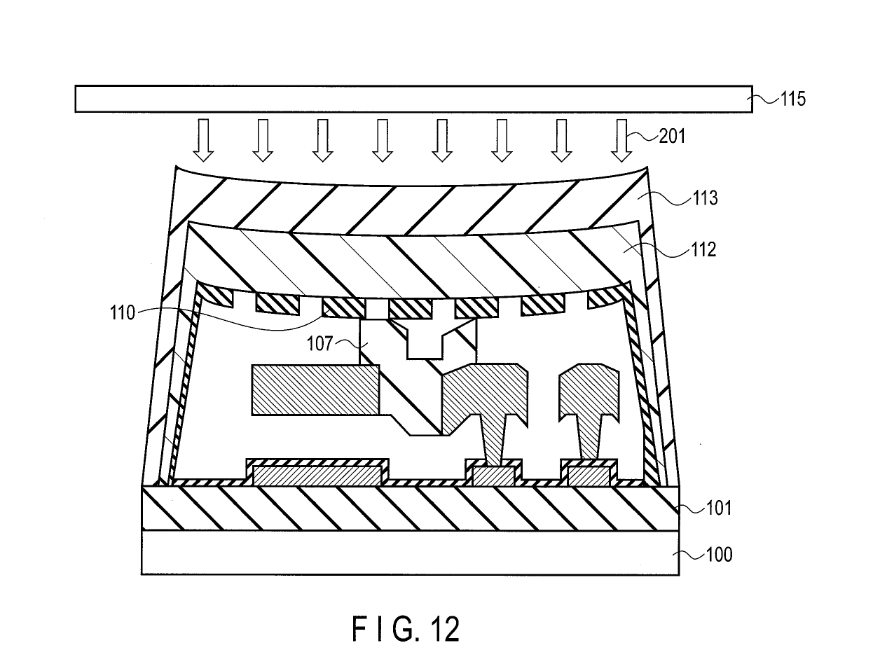

In a case where the upper surface of the third film 113 is flat or nearly flat (comparative example), when the dicing tape is applied to the third cap film 113, as shown in FIG. 12, the third film 113 positioned above the MEMS element receives the force 201 from the dicing tape 115, and the third film 113 positioned above the MEMS element is deformed. As a result, for example, a contact of the first cap film 110 to the connection portion 107 is occurred, which leads to a degradation of characteristics of the MEMS device. In the present embodiment, as mentioned above, the film 113A of the third cap film 113 does not occur, and thus, the contact of the first cap film 110 to the connection portion 107 is suppressed.

After that, well-known processes are followed. For example, a step of thinning the semiconductor substrate 100 (wafer) by polishing its back side in a state that the MEMS device is fixed by the dicing tape 115, a step of separating MEMS devices (chips) from the thinned substrate by dicing the thinned semiconductor substrate 100 are performed.

As described above, according to the present embodiment, in time of MEMS manufacturing, the thin-film dome on the substrate is suppressed from being deformed, where the thin-film dome and the substrate form the cavity containing the MEMS element. Thereby the yield and characteristics degradation of MEMS devices due to the thin-film dome is suppressed. As a result, the MEMS device having good accuracy and response, and the manufacturing method thereof can be provided.

### Second Embodiment

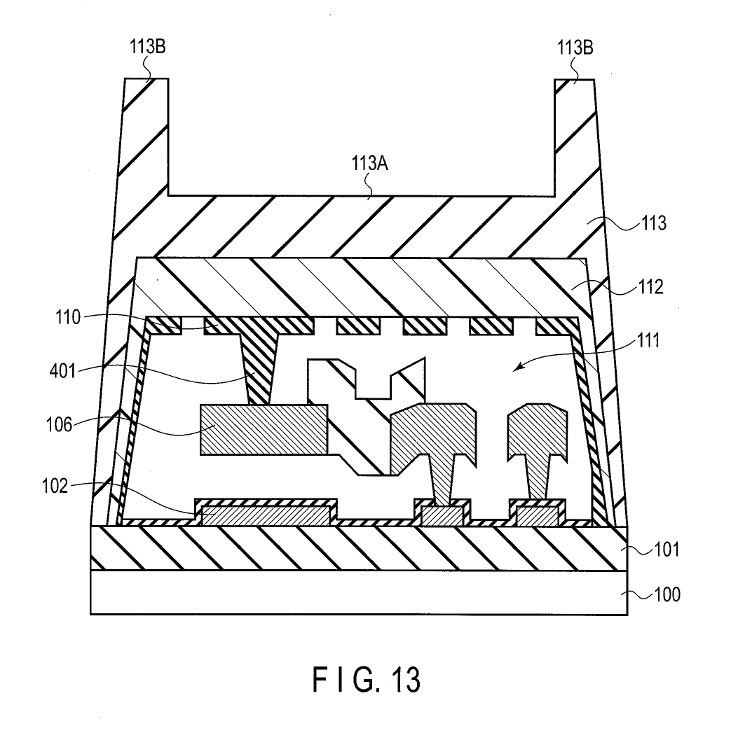

FIG. 13 is a sectional view for illustrating a MEMS device according to a second embodiment.

The present embodiment is different from the first embodiment in that the movable electrode 106 is connected to the thin-film dome (cap films 110, 112, 113) via an anchor member 401.

As a result, a pressure applied to the thin-film dome (cap films 110, 112, 113) is transmitted to the movable electrode 106, and thus the MEMS device having a function of pressure sensor is realized.

In order to increase a sensitivity of the pressure sensor, it is needed that the movable electrode 106 moves upward or downward in response to a change of ambient pressure to easily change a distance between the fixed electrode 102 and the movable electrode 106. For this purpose, a thickness of inner portion of the thin-film dome (cap films 110, 112, 113) should preferably be thinner. For example, the thickness of the film 113A is, for example, 3 to 5 μm. The thickness of upper portion of the second cap film 112 under the film 113A is also, for example, 3 to 5 μm. The thickness of the first cap film 110 under the upper portion of the second cap film 112 is, for example, 3 μm.

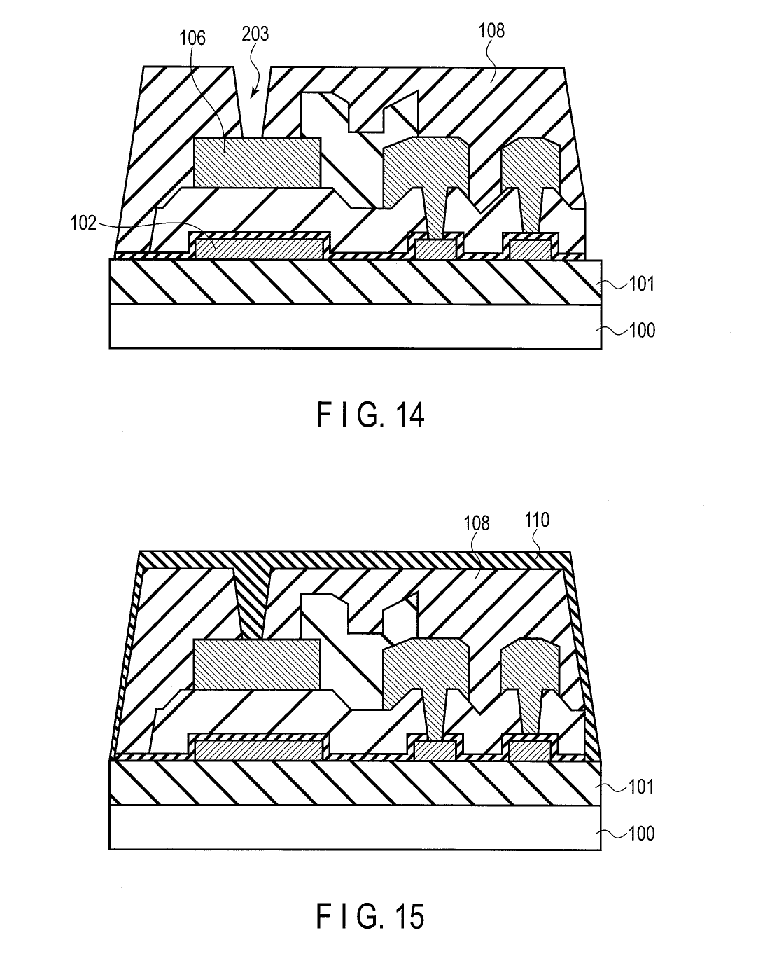

FIG. 14 and FIG. 15 are sectional views for illustrating an example of forming method of the anchor portion 401. In this forming method, the anchor portion 401 is formed from a same insulating film as the first cap film 110.

After the step of FIG. 5, as shown in FIG. 14, the second sacrifice layer 108 having an opening portion 203 in a region corresponding to the anchor portion 401 is formed. Next, as shown in FIG. 15, the insulating film 110 as the first cap film 110 and the anchor portion 401 is formed. The opening portion 203 shown in FIG. 14 is filled with the insulating film 110. After this, similar to the case of FIG. 6, the through hole is formed in the first cap film 110.

It is noted that the anchor portion 401 and the first cap film 110 may be formed of different materials each other. In this case, the first cap film 110 is formed after the anchor portion 401 is formed.

### Third Embodiment

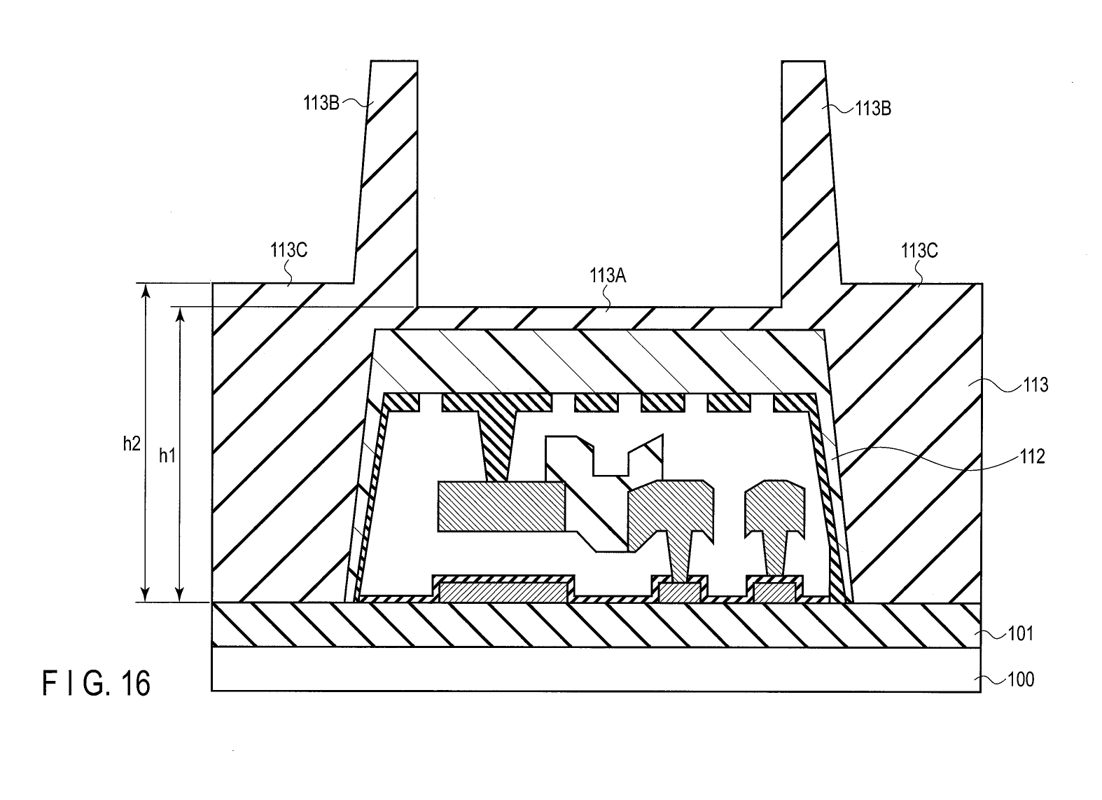

FIG. 16 is a sectional view for illustrating a MEMS device according to a third embodiment.

The present embodiment is different from the second embodiment in that the third cap film 113 comprises a film 113C formed in a third region. The film 113C is provided outside the film 113 B.

The third cap film 113 is thickened in lateral direction by the film 113C, thereby the thin-film dome is suppressed from being deformed by the force applied along the lateral direction. The lateral direction is for instance a direction perpendicular to a laminated direction of the films for instance.

Moreover, in the present embodiment, as shown in FIG. 16, the height h2 of the film 113 is greater than the height h1 of the film 113A, and the film 113C is thicker than the film 113A. Thereby, the force applied to the film 113B from the dicing tape at the time of applying the dicing tape (FIG. 11) is dispersed by the film 113C, and the load applied to the film 113B is reduced. As a result, the deformation of the film 113A positioned above the MEMS element is effectively suppressed.

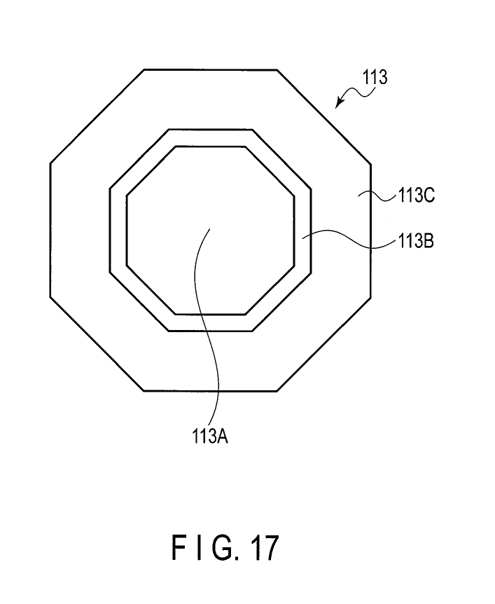

An example of a plane pattern of the third cap film 113 including the film 113C of the third embodiment is shown in FIG. 17. The third cap film 113 having an octagonal plane pattern is shown in FIG. 17.

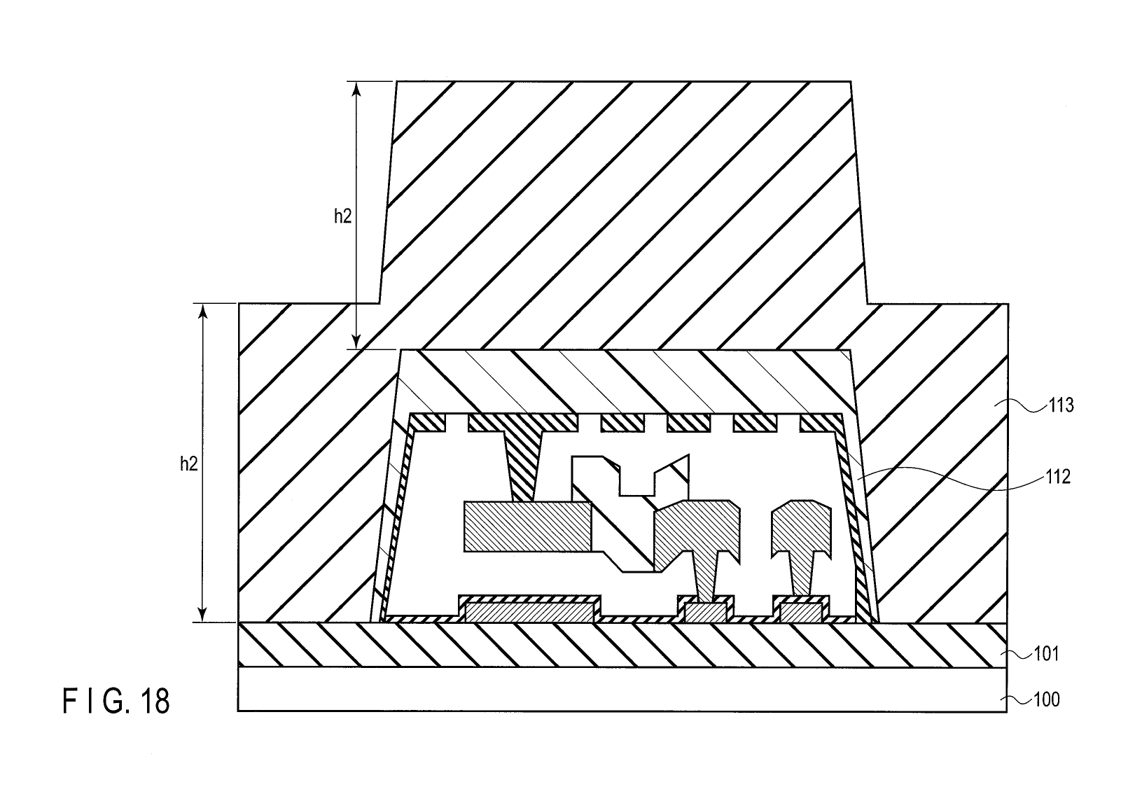

FIG. 18 to FIG. 20 are sectional views for illustrating an example of a forming method of the third cap film of the present embodiment.

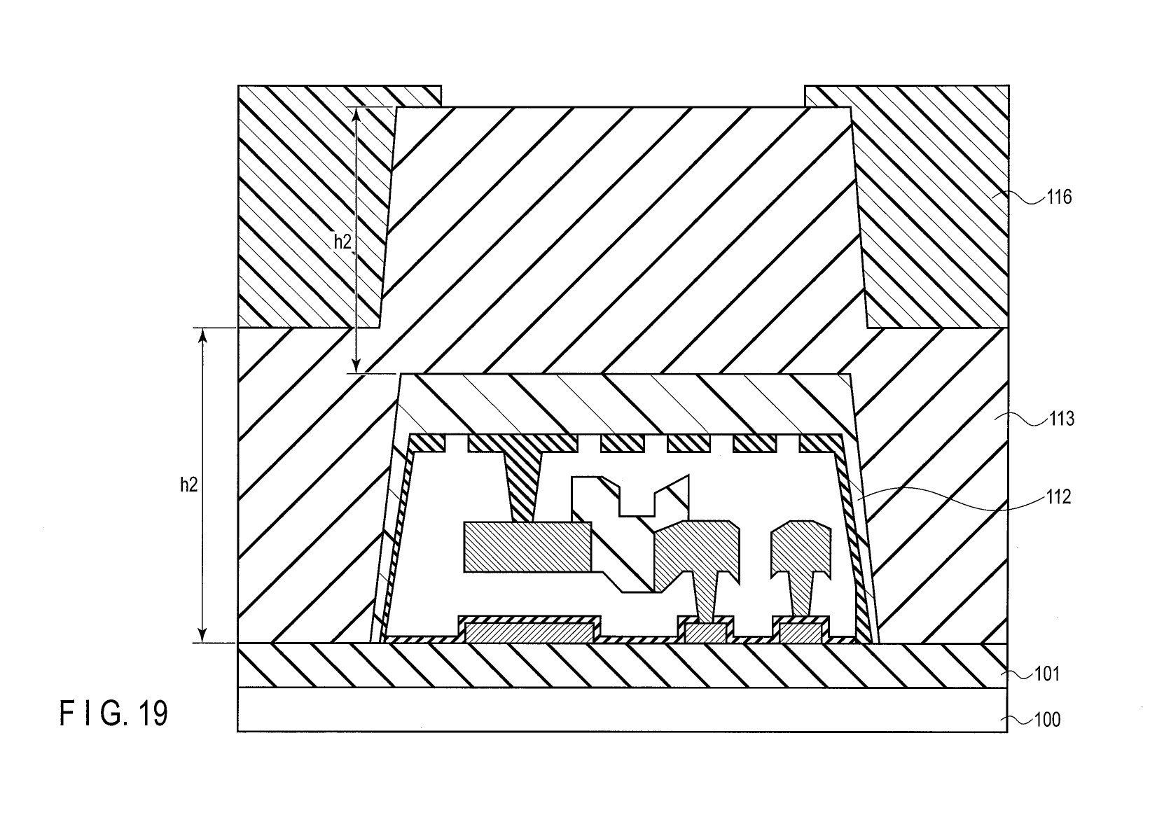

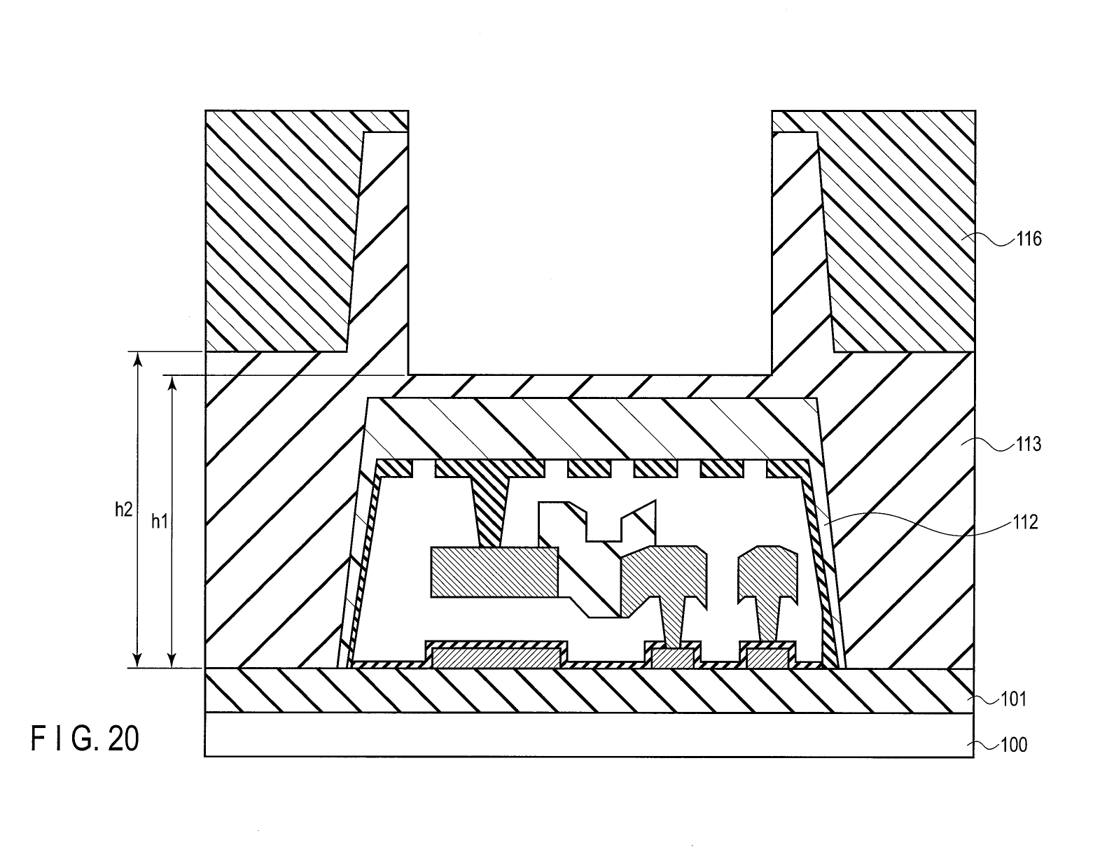

After the second cap film 112 is formed, as shown in FIG. 18, the insulating film 113 to be processed into the third cap film with thickness 2h is formed on the entire surface. Next, as shown in FIG. 19, a resist pattern 116 is formed on the insulating film 113, which covers portions to be the second region and the third region. And as shown in FIG. 20, the insulating film 113 is etched using the resist pattern 116 as a mask until the height of the portion to be the first region becomes h1, thereby the third cap film 113 including the first region, the second region and the third region is obtained. Thereafter, the resist pattern is removed.

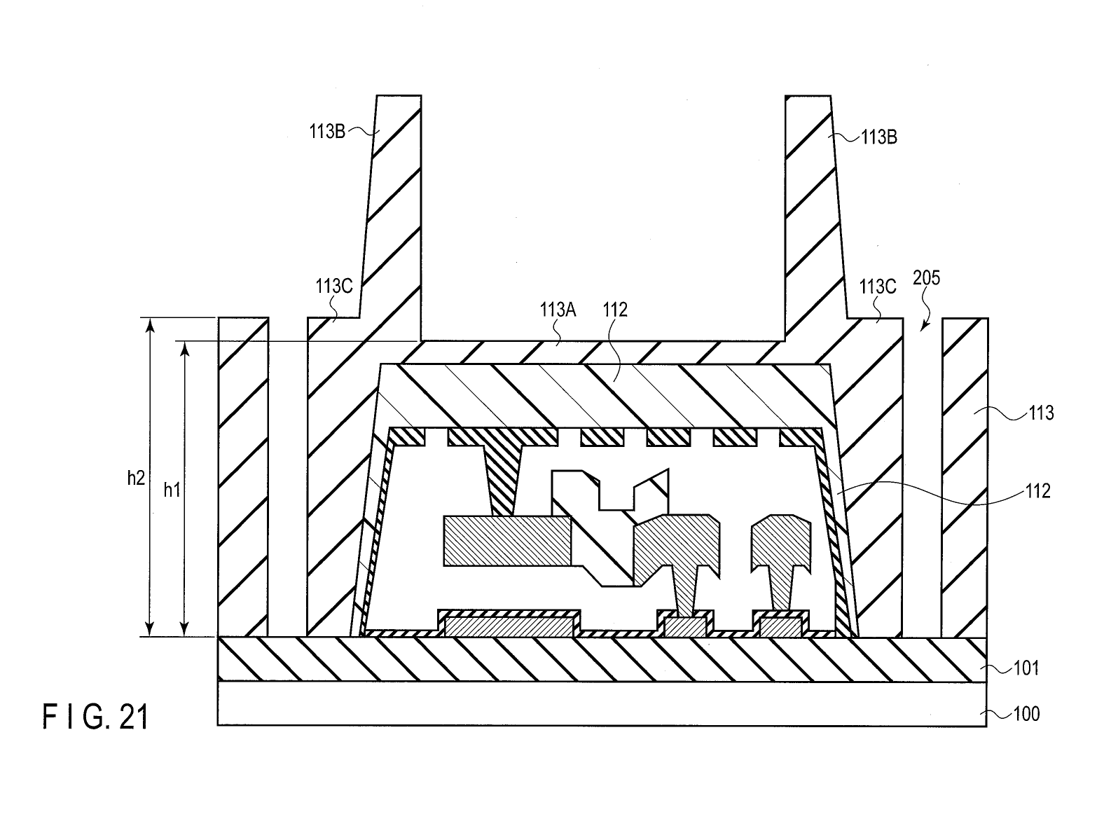

FIG. 21 is a sectional view for illustrating a variation of the MEMS device of the third embodiment. In this variation, a portion of the film 113C of the third cap film 113 is removed.

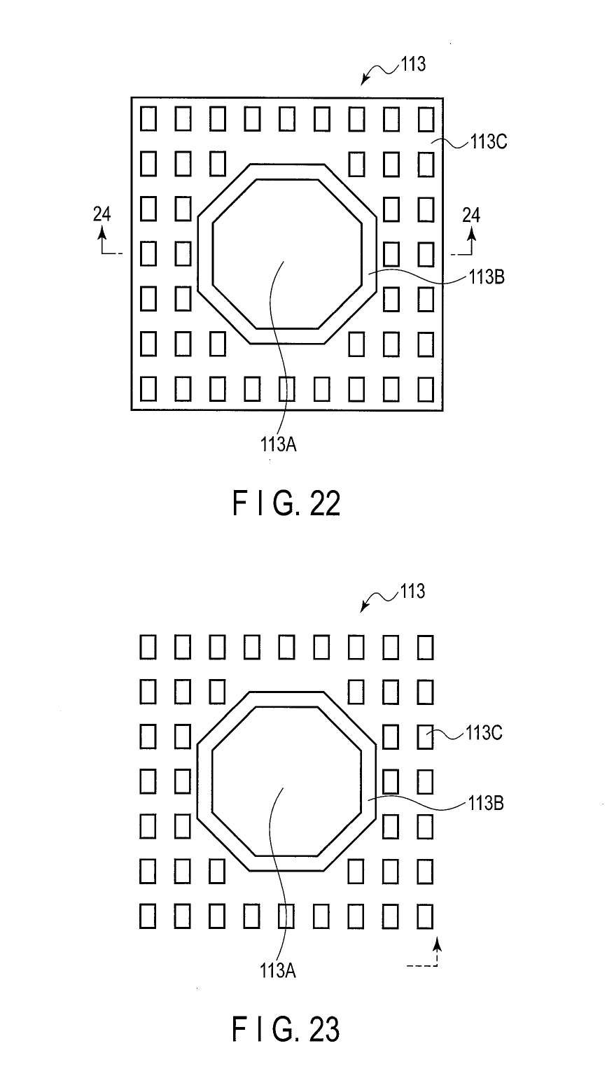

FIG. 22 is a plan view showing an example of a plane pattern of the third film 113 of the present variation. As shown in FIG. 22, the film 113C of the present variation has a lattice pattern. In other words, the film 113c comprises an insulator having opening portions.

FIG. 23 is a plan view for illustrating a third cap film 113 of another variation of the MEMS device of the present embodiment. As shown in FIG. 23, the film 113C of the present variation has a plurality of island shaped patterns. In other words, the film 113C comprises a plurality of island shaped insulators.

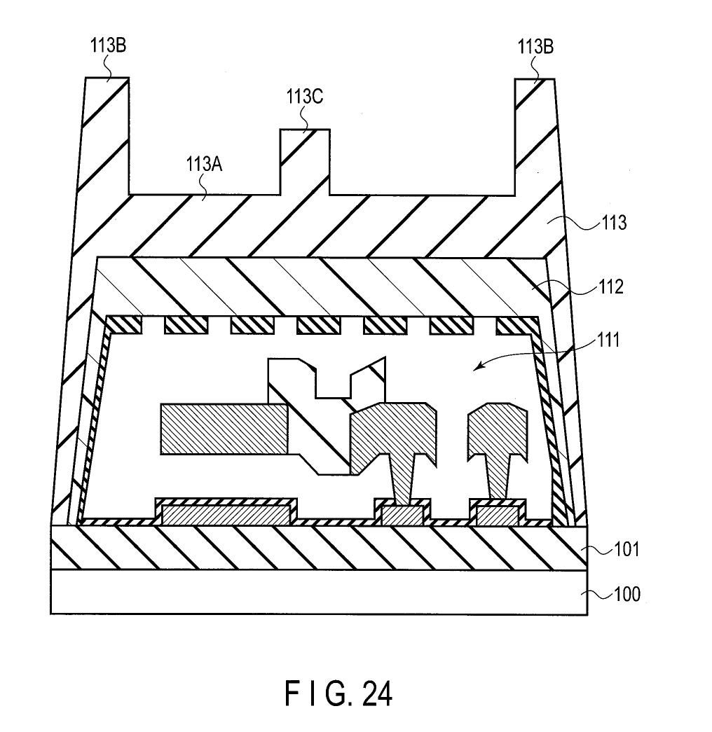

Moreover, as a variation of the first embodiment, for example, as shown in FIG. 24, a structure with a fourth region 113D of convex shape on the film 113A of the third cap film 113 can be provided.

The height of the fourth region 113D is set to be free from the force applied by the dicing 115 when the dicing tape 115 is applied to the third cap film 113. A plane pattern of the fourth region 113D is octagonal, for example.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A MEMS device comprising:
a substrate;
a MEMS element provided on the substrate;
a first film having a plurality of through holes, the first film and the substrate forming a cavity containing the MEMS element;
a second film provided on the first film;
a third film provided on the substrate, and comprising a first region and a second region outside the first region, the first region and the second region being different from each other in height from the substrate; and
the height from the substrate of the first region of the third film is lower than the height from the substrate of the second region of the third film.

2. The device of claim 1, wherein the first region of the third film is arranged above the MEMS element.

3. The device of claim 1, wherein the first region of the third film is thicker than the second region of the third film.

4. The device of claim 1, wherein the second region is arranged to surround the first region.

5. The device of claim 1, wherein the MEMS element comprises:
a first electrode fixed on the substrate;
a second electrode arranged above the first electrode to face the first electrode and being movable upward and downward;
an anchor member connecting the first film and the second electrode, and formed of a material that is same as that of the first film.

6. The device of claim 5, wherein the first region of the third film has a thickness for enabling the second film is to be move upward or downward in response to a change of ambient pressure.

7. The device of claim 1, wherein the third film further comprises a third region arranged outside the second region.

8. The device of claim 7, wherein height from the substrate of the third region of the third film is higher than that of the first region of the third film and lower than that of the second region of the third film.

9. The device of claim 8, wherein the third region has a pattern of a plurality of islands or a pattern of lattice.

10. The device of claim 1, wherein the second film-fills the plurality of through holes.

11. The device of claim 1, wherein the first film, the second film, and the third film are insulating films, respectively.

12. The device of claim 1, wherein the second film has a higher gas permeability than the first film.

13. The device of claim 1, wherein the third film has a lower gas permeability than the second film.

14. The device of claim 1, wherein the substrate includes a semiconductor substrate and an insulating film provided on the semiconductor substrate.

15. A method for manufacturing a MEMS device, comprising:
forming a MEMS element on a substrate;
forming a sacrifice layer covering the MEMS element on the substrate;
forming a first film having a plurality of through holes on the sacrifice layer;
removing the sacrifice layer via the plurality of through holes to form a cavity containing the MEMS element, wherein the cavity comprises the substrate and the first film.
forming a second film on the first film to close the plurality of through holes;
forming a third film comprising a first region and a second region outside the first region on the second film, wherein the first region and the second region are different in height from the substrate, and the height from the substrate of the first region of the third film is lower than that of the second region of the third film.

16. The method of claim 15, wherein the first region of the third film is arranged above the MEMS element.

17. The method of claim 15, wherein the forming the third film comprises:
forming a film to be processed into the third film,
forming a resist pattern on the film to be processed into the third film such that a region of the film to be processed into the third film corresponding to the first region is exposed, and a region of the film to be processed into the third film corresponding to the second region is covered by the resist pattern; and
etching the film to be processed into the third film by using the resist pattern as a mask in order to lower height of the region of the third film corresponding to the first region than height of the region of the third film corresponding to the second region.

18. The method of claim 15, wherein the forming the third film comprises forming a third region arranged outside the second region.

19. The method of claim 15, further comprising:
thinning the substrate after forming the third film, the thinning the substrate comprising polishing a back side of the substrate in a state that an adhesive face of a tape having adhesion is applied to the third film of the second region,
separating a plurality of chips from the thinned substrate by dicing the thinned substrate, each of the chips including the MEMS element, the first film, the second film and the third film.

20. The method of claim 15, wherein the substrate includes a semiconductor substrate, and an insulating film provided on the semiconductor substrate.
